(19) United States
(12) Patent Application Publication
(10) Pub. No.: US 2007/0011513 A1
(43) Pub. Date: Jan. 11, 2007

(54) Selective activation of error mitigation based on bit level error count

(75) Inventors: Arijit Biswas, Holden, MA (US); Steven E. Raasch, Shrewsbury, MA (US); Shubhendu S. Mukherjee, Framingham, MA (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(73) Assignee: Intel Corporation

(21) Appl. No.: 11/151,818

(22) Filed: Jun. 13, 2005

(51) Int. Cl. G11C 29/00

(52) U.S. Cl. 714/722

(57) ABSTRACT

Embodiments of apparatuses and methods for selective activation of error mitigation based on bit level error counts are disclosed. In one embodiment, an apparatus includes a plurality of state elements, an error counter, and activation logic. The error counter is to count the number of bit level errors in the state elements. The activation logic is to increase error mitigation if the number of bit level errors exceeds a threshold value.

### BACKGROUND

1. Field

The present disclosure pertains to the field of data processing, and more particularly, to the field of error mitigation in data processing apparatuses.

2. Description of Related Art

As improvements in integrated circuit manufacturing technologies continue to provide for smaller dimensions and lower operating voltages in microprocessors and other data processing apparatuses, makers and users of these devices are becoming increasingly concerned with the phenomenon of soft errors. Soft errors arise when alpha particles and high-energy neutrons strike integrated circuits and alter the charges stored on the circuit nodes. If the charge alteration is sufficiently large, the voltage on a node may be changed from a level that represents one logic state to a level that represents a different logic state, in which case the information stored on that node becomes corrupted. Generally, soft error rates (“SER”s) increase as circuit dimensions decrease, because the likelihood that a striking particle will hit a voltage node increases when circuit density increases. Likewise, as operating voltages decrease, the difference between the voltage levels that represent different logic states decreases, so less energy is needed to alter the logic states on circuit nodes and more soft errors arise.

Blocking the particles that cause soft errors is extremely difficult, so data processing apparatuses often include techniques for detecting, and sometimes correcting, soft errors. These error mitigation techniques include using error-correcting-codes (“ECC”), scrubbing caches, and running processors in lockstep. However, the use of error mitigation techniques tends to reduce performance and increase power consumption. Furthermore, the necessity or desirability of using error mitigation may vary according to the time and place in which the device is being used, because environmental factors such as altitude, magnetic field strength and direction, and solar activity may influence the SER.

Therefore, selective activation of error mitigation may be desired.

### BRIEF DESCRIPTION OF THE FIGURES

The present invention is illustrated by way of example and not limitation in the accompanying figures.

FIG. 1 illustrates an embodiment of the present invention in a processor.

FIG. 2 illustrates a multicore processor according to an embodiment of the present invention.

FIG. 3 illustrates a system according to an embodiment of the present invention.

FIG. 4 illustrates an embodiment of the present invention in a method of selectively activating error mitigation based on bit level error count

### DETAILED DESCRIPTION

The following describes embodiments of selective activation of error mitigation based on bit level error count. In the following description, numerous specific details, such as component and system configurations, may be set forth in order to provide a more thorough understanding of the present invention. It will be appreciated, however, by one skilled in the art, that the invention may be practiced without such specific details. Additionally, some well known structures, circuits, techniques, and the like have not been described in detail, to avoid unnecessarily obscuring the present invention.

Due to the random nature of the particle flux responsible for soft errors, a reasonable assessment of the SER may require a relatively large area for error detection. The present invention may be desirable because it provides for error detection using structures, such as cache memories and scan cells, that may already account for a significant portion of the die size of many processors and other devices. Therefore, the present invention may be implemented without requiring additional error detection structures that could significantly increase die size, and therefore cost.

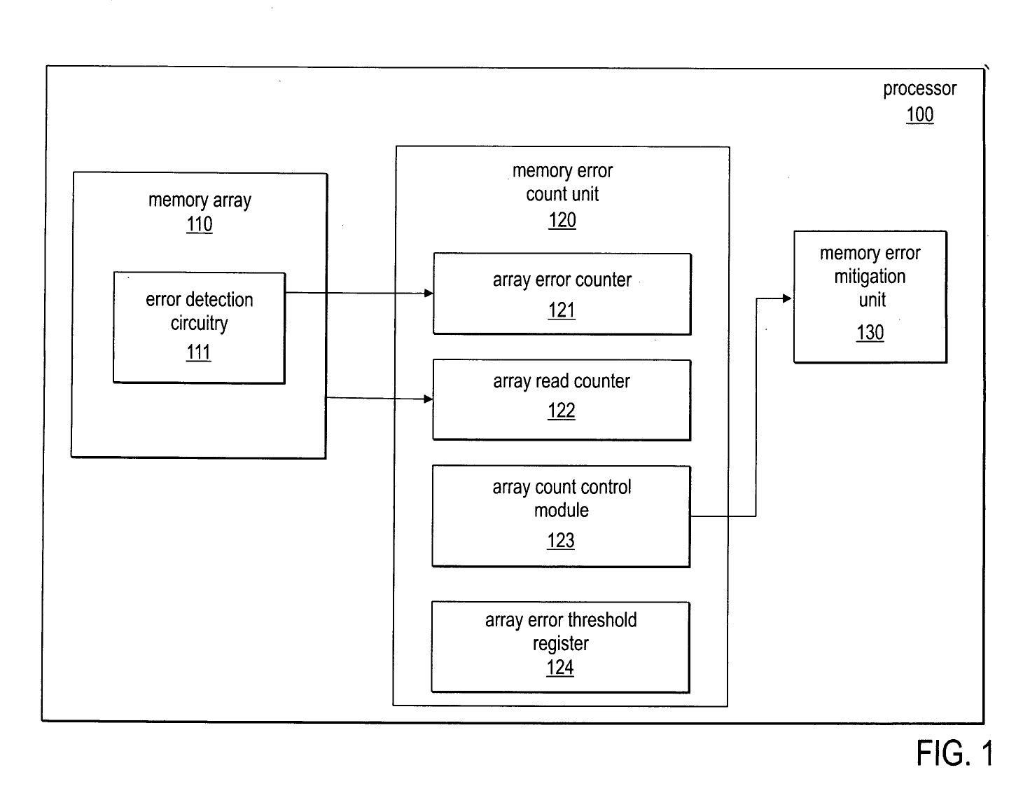

FIG. 1 illustrates an embodiment of the present invention in processor 100. Processor 100 may be any of a variety of different types of processors, such as a processor in the Pentium® Processor Family, the Itanium® Processor Family, or other processor family from Intel Corporation, or another processor from another company. The present invention may also be embodied in an apparatus other than a processor, such as a memory device. Processor 100 includes memory array 110, memory error count unit 120, and memory error mitigation unit 130.

Memory array 110 may be any number of rows and any number of columns of any type of memory cells, such as static random access memory cells, used for any function, such as a cache memory. Memory array 110 includes error detection circuitry 111 to detect bit level errors in memory array 110, using any known technique, such as parity or ECC. Many processor and other device designs include relatively large areas for cache or other memory arrays, and many of these arrays already include parity or ECC. Therefore, a significant area of the die may be available at a low cost for error detection according to the present invention.

Memory error count unit 120 includes array error counter 121, array read counter 122, and array count control module 123. Array error counter 121 may be any known counter circuit, synchronous or asynchronous, having a count input, a count output, and a reset. The count input of array error counter 121 is coupled to error detection circuitry 111 to receive a signal indicating that a bit level error has been detected on a read of memory array 110, such that the count output of array error counter 121 indicates the total number of bit level errors detected on reads of memory array 110 since array error counter 121 has been reset.

Array read counter 122 may also be any known counter circuit, synchronous or asynchronous, having a count input, a count output, and a reset. The input of array read counter 122 is coupled to memory array 110 to receive a signal indicating that memory array 110 is being read, such that the count output of array read counter 122 indicates the total number of times that memory array 110 has been read since array read counter 122 has been reset.

In this embodiment, array error counter 121 and array read counter 122 are reset whenever the number of reads of memory array 110 counted by array read counter 122 reaches a certain limit, e.g., every 1,000 reads. This array read limit value may be fixed or programmable. An appropriate array read limit value may be chosen based on the size, in number of bits, and area of memory array 110, the expectation of the number of reads needed for a reasonably accurate determination of the SER, and any other factors. Array error counter 121 and array read counter 122 are also reset after a certain time (e.g., measured in seconds) has passed, so that changes in the SER may be detected even if memory array 110 is relatively inactive. In other embodiments, the counters may also, or instead, be reset based on any other event or signal.

In this embodiment, the output of array error counter 121 is coupled to array count control module 123, such that array count control module 123 receives the number of bit level errors per the array read limit value whenever array error counter 121 and array read counter 122 are reset. In other embodiments, the number of bit level errors may be continuously available to array count control module 123, or may be sent to array count control module 123 based on any other event or signal.

Array count control module 123 also includes array error threshold register 124, which may be programmed to hold an array error threshold value. In other embodiments, the array error threshold value may be fixed. If the number of bit level errors exceeds the array error threshold value, then error mitigation is to be activated or increased. An appropriate array error threshold value may be chosen based on the number of bit level errors per array read limit value that corresponds to the desired SER threshold. Other embodiments may include logic to calculate the SER from the outputs of counters 121 and 122. The determination of whether the number of bit level errors exceeds the array error threshold value may be performed using any known approach, such as using a comparator circuit.

Array count control module 123 indicates to memory error mitigation unit 130 whether the number of bit level errors exceeds the array error threshold value. The indication may be based on the state or transition of a signal (a “high SER” signal) or any other known approach. If array count control module 123 indicates that the array error threshold has been exceeded, memory error mitigation unit 130 activates or increases error mitigation through any one or more of a variety of known approaches. For example, memory error mitigation unit 130 may activate scrubbing of memory array 110, or may increase the frequency of periodic scrubbing of memory array 110.

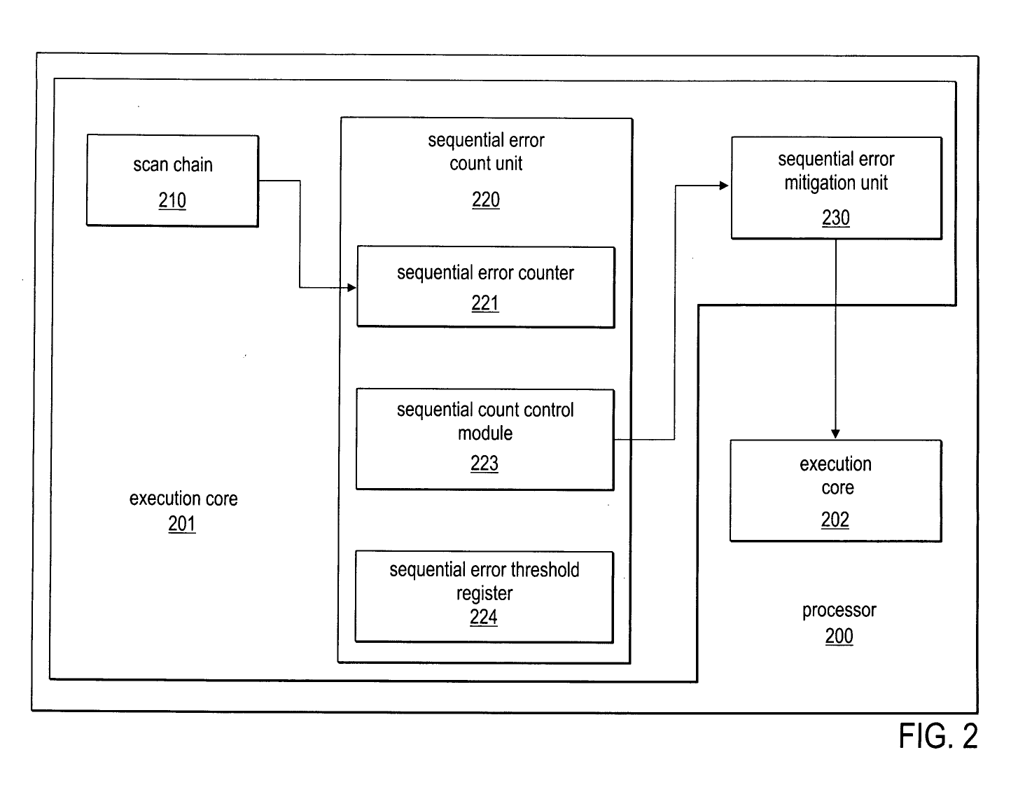

As shown in FIG. 2, the present invention may also be embodied using sequential logic for error detection instead of a memory array. FIG. 2 illustrates multicore processor 200 according to an embodiment of the present invention. Generally, a multicore processor is a single integrated circuit including more than one execution core. An execution core includes logic for executing instructions. In addition to the execution cores, a multicore processor may include any combination of dedicated or shared resources within the scope of the present invention. A dedicated resource may be a resource dedicated to a single core, such as a dedicated level one cache, or may be a resource dedicated to any subset of the cores. A shared resource may be a resource shared by all of the cores, such as a shared level two cache or a shared external bus unit supporting an interface between the multicore processor and another component, or may be a resource shared by any subset of the cores.

Multicore processor 200 includes execution core 201 and execution core 202. Execution core 201 includes scan chain 210, sequential error count unit 220, and sequential error mitigation unit 230.

Scan chain 210 may be any number of scan cells connected in a series arrangement, such as a daisy chain or shift register arrangement. Scan cells are sequential elements, such as latches or flip-flops, that are added to many integrated circuits to provide redundant state information for testing and debugging of sequential logic. The scan cells are arranged in a chain that may be used to sequentially shift data out of a device, or to place a device into a known state by sequentially transferring data into a device. Typically, the scan cells are disabled prior to the device leaving the factory.

Many processor designs include scan cells, and many include “full scan” capability, which means that there is a scan cell for all sequential states of the processor. Therefore, a significant area of the processor die, perhaps roughly as much area as that of the sequential circuitry of the processor, may be available at a low cost for error detection according to the present invention. To further increase error detection capability, existing scan cell designs may be modified to increase their sensitivity to soft errors. These design modifications, such as adding or removing capacitance and increasing channel length, may be made without hindering functionality for normal scan operation, and may be made in such a way that they may be disabled for normal scan operation and enabled for soft error detection. Accordingly, scan cells included on a processor or other device for testing and debugging may be also or alternatively be configured for soft error detection.

Error detection may be performed by constantly shifting a known data value into the input of scan chain 210, and observing the output. Errors will be indicated by a different value arriving at the output of scan chain 210. For example, the input of scan chain 210 may be set to binary zero. Each binary one arriving at the output of scan chain 210 indicates one bit level error. Observing zero to one, rather than one to zero transitions, may be desirable in an n-well process, where a zero to one transition can be caused by both alpha and neutron particle strikes, but one to zero transitions can only be caused by neutrons.

Sequential error count unit 220 includes sequential error counter 221 and sequential count control module 223. Sequential error counter 221 may be any known counter circuit, synchronous or asynchronous, having a count input, a count output, and a reset. The count input of sequential error counter 221 is coupled to the output of scan chain 210, such that the count output of sequential error counter 221 indicates the total number of bit level errors detected by scan chain 210 since sequential error counter 221 has been reset. In this embodiment, sequential error counter 221 is reset after each full shift of scan chain 210, i.e., the number of clock cycles needed for a value injected at the input to reach the output. In other embodiments, the counters may also, or instead, be reset based on any other event or signal.

In this embodiment, the output of sequential error counter 221 is coupled to sequential count control module 223, such that sequential count control module 223 receives the number of bit level errors per full scan whenever sequential error counter 221 is reset. In other embodiments, the number of bit level errors may be continuously available to sequential count control module 223, or may be sent to sequential count control module 223 based on any other event or signal.

Sequential count control module 223 also includes sequential error threshold register 224, which may be programmed to hold a sequential error threshold value. In other embodiments, the array error threshold value may be fixed. If the number of bit level errors exceeds the sequential error threshold value, then error mitigation is to be activated or increased. An appropriate sequential error threshold value may be chosen based on the number of scan cells in scan chain 210. Other embodiments may include a scan counter to count the number of partial or full scans, and logic to calculate the SER from the outputs of an error counter and the scan counter. The determination of whether the number of bit level errors exceeds the sequential error threshold value may be performed using any known approach, such as using a comparator circuit.

Sequential count control module 223 indicates to sequential error mitigation unit 230 whether the number of bit level errors exceeds the sequential error threshold value. The indication may be based on the state or transition of a high SER signal or any other known approach. If sequential count control module 223 indicates that the sequential error threshold has been exceeded, sequential error mitigation unit 230 activates or increases error mitigation through any one or more of a variety of known approaches. For example, sequential error mitigation unit 230 may activate execution core 202 to run in lockstep with execution core 201.

The present invention may also be embodied in an apparatus using any combination of memory arrays, scan chains, or any other structures having state elements in which bit level errors may be detected. For example, a processor may include two or more memory arrays, each with its own corresponding error count and mitigation units, or two or more execution cores, each with its own corresponding scan chain and error count and mitigation units. Each error count unit may include one or more threshold registers to provide for the threshold values to be calibrated to account for factors such as process and architectural vulnerability. The threshold registers may be programmable to allow tuning of the threshold values.

In some embodiments, a single error count unit may include multiple counters for different sources or types of errors, and/or high SER signals from multiple error count units may be processed together to determine if, what type, and at what level error mitigation is activated. In one such embodiment, high SER signals may be OR'd together. For example, error mitigation may be activated if one or both of an array error threshold and a sequential error threshold have been exceeded. In another such embodiment, a determination of whether an error threshold has been exceeded may be based on a combination of error counts from more than one counter. The counts may be added together directly, or one count may be weighted more heavily than another because one type or source of error represents a greater reliability concern. Within the scope of the present invention, other forms of processing error counts and/or high SER signals are also possible, such as providing for one specific high SER signal to negate or override another specific high SER signal.

In any of these or any other embodiments, various levels or types of error mitigation may be activated or increased, depending on the source and/or processing of the high SER signals. For example, in an embodiment with error detection for both of a cache and sequential logic, a high SER signal from only the cache may activate cache scrubbing, a high SER signal from only the sequential logic may activate lockstepping, and a high SER signal from both may activate an increase in operating voltage.

Furthermore, embodiments may include multiple error threshold values for a single error count unit, so that the type or level of error mitigation may be chosen depending on the detected magnitude of the SER. In one such embodiment, multiple tiers of error mitigation may be available, for example, and different high SER signals may be used to indicate which tier of error mitigation to choose based on which error threshold has been exceeded. These tiers may be distinguished by different levels of a single technique, such as varying frequencies of cache scrubbing, or may be distinguished by the use of different techniques, such as cache scrubbing in one tier and increasing the operating voltage in another tier. In one or more of the tiers, one or more error mitigation technique may be inactive or in an off state. In each of the other tiers, the same error mitigation state may be on or activated at one of a single or multiple levels.

Embodiments of the present invention may include any combination of the above. An embodiment may include multiple error counters, each with multiple error thresholds, and multiple tiers of error mitigation being chosen based on processing of the high SER signals. The processing may be performed to give more weight to certain types or sources of errors. For example, a certain tier of error mitigation may be entered if a high SER signal from a large memory is asserted or both high SER signals from two smaller memory arrays are asserted. As another example, a certain tier of error mitigation may be entered if a high SER signal from a scan chain is asserted, and an even higher level or tier of error mitigation may be entered if a high SER signal from a memory array is asserted, because the memory array represents a greater portion of the die area than the scan chain.

In some embodiments, the timing of the high SER signals, counter outputs, and other signals is not critical because the goal may be to detect sustained periods of high SER rather than short spikes. Therefore, the signals may be pipelined or delayed, and may arrive from different units at different times. Additionally, hysteresis in the high SER signal may be desired, and/or a few iterations of error detection may be performed before activating, increasing, deactivating, or decreasing error mitigation to avoid thrashing between error mitigation modes.

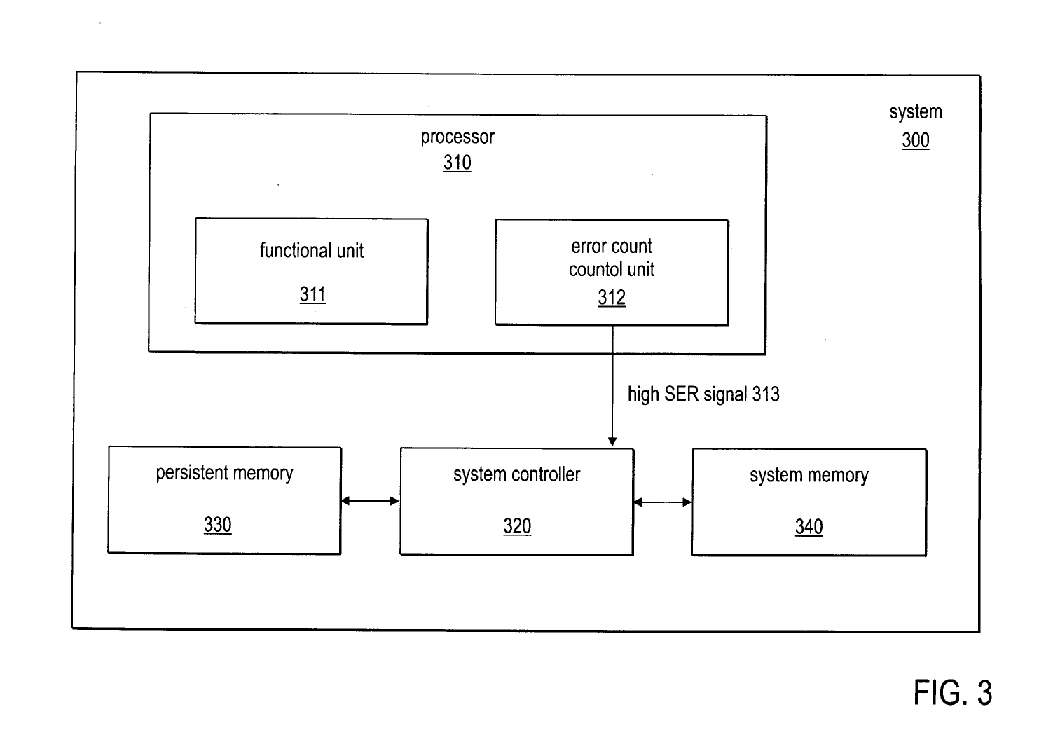

FIG. 3 illustrates system 300 according to an embodiment of the present invention. System 300 includes processor 310, system controller 320, persistent memory 330 and system memory 340. Processor 310 may be any processor as described above, including functional unit 311 and error count control unit 312. Functional unit 311 includes a memory array, sequential logic, or any other structures having state elements in which bit level errors may be detected. Error count control unit 312 counts the number of bit level errors in functional unit 311 and indicates whether the number of bit level errors in functional unit 311 exceeds an error threshold value. In this embodiment, error count control unit 312 asserts high SER signal 313 if the number of bit level errors in functional unit 311 exceeds the error threshold value.

System controller 320 may be any chipset component or other component coupled to processor 310 to receive high SER signal 313. In this embodiment, of high SER signal 313 is asserted, system controller 320 activates or increases error mitigation. For example, system controller 320 may include or be coupled to a voltage controller that would raise the system, processor, or other voltage level to mitigate soft errors.

System controller 320 may also include or be coupled to persistent memory 330 for storing the state of high SER signal 313, or for otherwise retaining information regarding the detected SER. Persistent memory 330 may be any memory capable of retaining information while system 300 or processor 310 is in an off or other inactive state. For example, persistent memory 330 may be flash memory or non-volatile or battery backed random access memory. Therefore, in the event that system 300 crashes, due to a soft error or otherwise, system controller 320 may read persistent memory 330 upon reboot to determine if the most recently detected SER was high, and if so, reboot system 300 with error mitigation activated.

System memory 340 may be any type of memory, such as static or dynamic random access memory or magnetic or optical disk memory. System memory 340 may be used to store instructions to be executed by and data to be operated on by processor 320, or any information in any form, such as operating system software, application software, or user data.

Processor 310, system controller 320, persistent memory 330, and system memory 340 may be coupled to each other in any arrangement, with any combination buses or direct or point-to-point connections, and through any other components. System 300 may also include any buses, such as a peripheral bus, or components, such as input/output devices, not shown in FIG. 3.

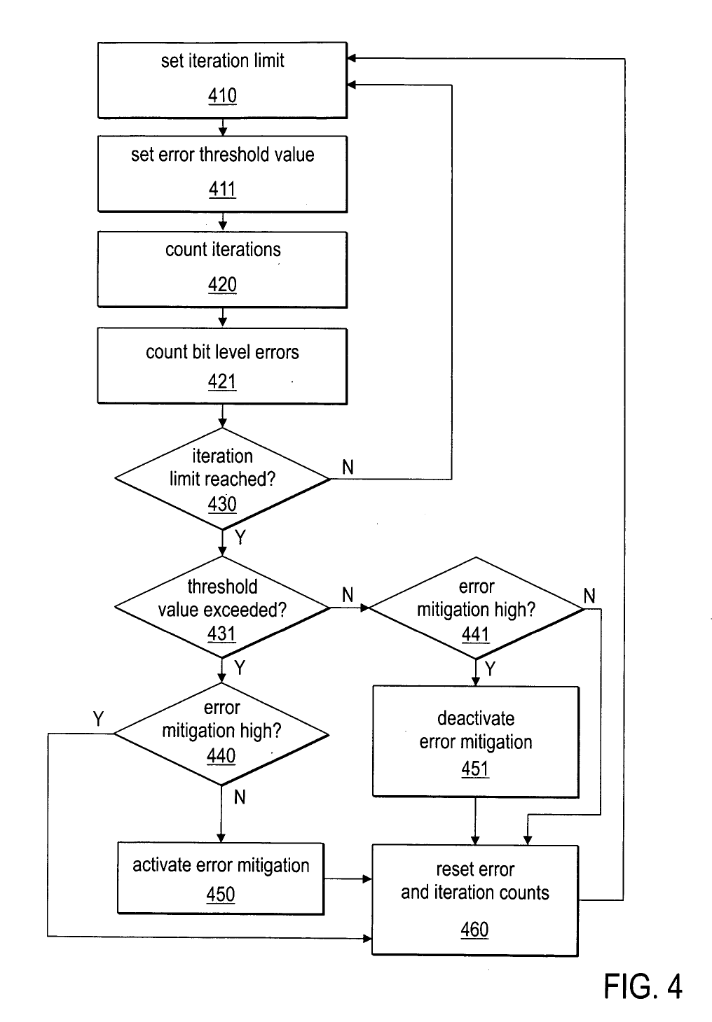

FIG. 4 illustrates an embodiment of the present invention in a method of selectively activating error mitigation based on bit level error count. In the embodiment of FIG. 4, error mitigation may be in one of two modes, high or low. The high mode may be an on mode and the low mode may be an off mode, or error mitigation may be on in both modes but operating at a higher level or frequency in the high mode than in the low mode. Error mitigation in the embodiment of FIG. 4 may include any known approach. For example, the high mode may include cache scrubbing, running two or more processor cores in lockstep, or running a device or a portion of a device at the higher of two operating voltages. The low mode may include a lower frequency of cache scrubbing or none at all, running a single processor core alone or two or more not in lockstep, or running a device at the lower of two operating voltages.

In box 410, an iteration limit is programmed into an iteration limit register for a functional block in a processor or other device. The functional block includes a memory array, sequential logic, or any other structure having state elements. The iteration limit may be based on the number of state elements in the functional block, the size, area, configuration, architecture, or function of the functional block, the process technology used to manufacture the device, the expected use or environment for use of the device, or any other factors.

In box 411, an error threshold value is programmed into an error threshold register for the functional block. The error threshold value may be based on the same factors as the iteration limit, plus additional factors such as the iteration limit itself, and the expected SER.

In box 420, the number of iterations of an event is counted while the functional block is in use. The event may be any event that can be counted as the denominator in a calculation of error rate. For example, the event may be read accesses to a memory array, or full scans of a scan chain. The number of iterations may be counted using any type of counter.

In box 421, the number of bit level errors in the state elements is counted while the functional block is in use. The bit level errors may be detected using any known technique, such as parity for a memory array or injecting a known value into the input of a scan chain and observing the output for sequential logic. The number of bit level errors may be counted using any type of counter.

In box 430, a determination is made as to whether the number of iterations counted in box 420 has reached the iteration limit. The determination may be made according to any known approach, such as basing it on a particular bit of an iteration counter output, or comparing an iteration counter output to the contents of an iteration limit register. When the number of iterations reaches the iteration limit, the method continues to box 431. Until then, the method continues with box 420.

In box 431, a determination is made as to whether the number of errors counted in box 421 exceeds the error threshold value. The determination may be made according to any known approach, such as comparing an error counter output to the contents of an error threshold register. If the number of errors counted exceeds the threshold value, the method continues to box 440. If not, the method continues to box 441.

In boxes 440 and 441, a determination is made as to whether error mitigation is in a high mode or a low mode. If in a low mode, the method continues from box 440 to box 450, or from box 441 to box 460. If in a high mode, the method continues from box 440 to box 451, or from box 441 to box 460.

In box 450, error mitigation is activated or increased from the low mode to the high mode. In box 451, error mitigation is deactivated or decreased from the high mode to the low mode. From boxes 450 and 451, the method continues to box 460. In box 460, the iteration and error counts are reset. From box 460, the method returns to box 420.

Within the scope of the present invention, the method illustrated in FIG. 4 may be performed in a different order, with illustrated steps omitted, with additional steps added, or with a combination of reordered, omitted, or additional steps. For example, box 410 and all references to an iteration count may be omitted in an embodiment where the error count is compared to a threshold value based on single full shift through a scan chain. As another example, the determinations as to whether error mitigation is in a high or a low mode may be omitted in an embodiment where there is no difference between the implementation of staying in a high mode and the implementation of going from a low mode to a high mode. Furthermore, the present invention may be embodied in methods where the determination as to whether to activate error mitigation may be based on more than one error count from more than one functional unit, and an in methods including more than two error mitigation modes.

Processor 100, processor 200, or any other component or portion of a component designed according to an embodiment of the present invention may be designed in various stages, from creation to simulation to fabrication. Data representing a design may represent the design in a number of manners. First, as is useful in simulations, the hardware may be represented using a hardware description language or another functional description language. Additionally or alternatively, a circuit level model with logic and/or transistor gates may be produced at some stages of the design process. Furthermore, most designs, at some stage, reach a level where they may be modeled with data representing the physical placement of various devices. In the case where conventional semiconductor fabrication techniques are used, the data representing the device placement model may be the data specifying the presence or absence of various features on different mask layers for masks used to produce an integrated circuit.

In any representation of the design, the data may be stored in any form of a machine-readable medium. An optical or electrical wave modulated or otherwise generated to transmit such information, a memory, or a magnetic or optical storage medium, such as a disc, may be the machine-readable medium. Any of these media may “carry” or “indicate” the design, or other information used in an embodiment of the present invention, such as the instructions in an error recovery routine. When an electrical carrier wave indicating or carrying the information is transmitted, to the extent that copying, buffering, or re-transmission of the electrical signal is performed, a new copy is made. Thus, the acts of a communication provider or a network provider may be acts of making copies of an article, e.g., a carrier wave, embodying techniques of the present invention.

Thus, selective activation of error mitigation based on bit level error count has been disclosed. While certain embodiments have been described, and shown in the accompanying drawings, it is to be understood that such embodiments are merely illustrative of and not restrictive on the broad invention, and that this invention not be limited to the specific constructions and arrangements shown and described, since various other modifications may occur to those ordinarily skilled in the art upon studying this disclosure. For example, increasing error mitigation may include increasing error mitigation from an off mode to an on mode, and increasing error mitigation when an error count exceeds an error threshold value may include increasing error mitigation when the error count equals or exceeds the error threshold.

In an area of technology such as this, where growth is fast and further advancements are not easily foreseen, the disclosed embodiments may be readily modifiable in arrangement and detail as facilitated by enabling technological advancements without departing from the principles of the present disclosure or the scope of the accompanying claims.

What is claimed is:

1. An apparatus comprising:
a plurality of state elements;
an error counter to count the number of bit level errors in the plurality of state elements; and
activation logic to increase error mitigation if the number of bit level errors exceeds a threshold value.

2. The apparatus of claim 1, wherein the activation logic is to increase error mitigation from an off mode to an on mode.

3. The apparatus of claim 1, further comprising a programmable register to store the threshold value.

4. The apparatus of claim 1, wherein the plurality of state elements includes an array of memory cells.

5. The apparatus of claim 4, further comprising an access counter to count accesses to the array of memory cells.

6. The apparatus of claim 5, wherein the error counter is reset based on the number of accesses to the array of memory cells.

7. The apparatus of claim 6, wherein the error counter is also reset based on time.

8. The apparatus of claim 4, further comprising error detection logic to detect bit level errors in the array of memory cells.

9. The apparatus of claim 6, wherein the error detection logic includes parity checking logic.

10. The apparatus of claim 4, wherein the activation logic is to increase scrubbing of the array of memory cells.

11. The apparatus of claim 1, wherein the plurality of state elements includes a plurality of scan cells.

12. The apparatus of claim 11, wherein the plurality of scan cells are configured for soft error detection.

13. The apparatus of claim 11, wherein the plurality of scan cells are arranged in a scan chain.

14. The apparatus of claim 13, wherein the error counter is reset based on a full shift through the scan chain.

15. An apparatus comprising:
a plurality of execution cores, wherein a first of the plurality of execution cores includes a plurality of state elements;
an error counter to count the number of bit level errors in the plurality of state elements; and
activation logic to activate lockstepping of the first and a second of the plurality of execution cores if the number of bit level errors exceeds a threshold value.

16. A method comprising:
counting the number of bit level errors in a plurality of state elements; and
increasing error mitigation if the number of bit level errors exceeds a threshold value.

17. The method of claim 16, wherein increasing error mitigation includes increasing error mitigation from an off mode to an on mode.

18. The method of claim 16, further comprising storing the threshold value in a programmable register.

19. The method of claim 16, wherein the plurality of state elements includes an array of memory cells, further comprising:
counting the number of accesses to the array of memory cells; and
resetting the count of the number of bit level errors based on the number of accesses to the array of memory cells.

20. The method of claim 19, wherein increasing error mitigation includes increasing scrubbing of the array of memory cells.

21. The method of claim 16, wherein the plurality of state elements includes a chain of scan cells, further comprising resetting the count of the number of bit level errors after a full shift through the chain of scan cells.

22. A system comprising:
a processor including:
a plurality of state elements;
an error counter to count the number of bit level errors in the plurality of state elements; and
control logic to indicate whether the number of bit level errors exceeds a threshold value; and
a system controller to increase error mitigation if the control logic indicates that the number of bit level errors exceeds the threshold value.

23. The system of claim 22, wherein the activation logic is to increase error mitigation from an off mode to an on mode.

24. The system of claim 22, further comprising a persistent memory to store an indication of whether the number of bit level errors exceeds the threshold value.

25. A system comprising:
a dynamic random access memory;
a processor including:
a plurality of state elements;
an error counter to count the number of bit level errors in the plurality of state elements; and
control logic to indicate whether the number of bit level errors exceeds a threshold value; and
activation logic to increase error mitigation if the control logic indicates that the number of bit level errors exceeds the threshold value.
